(19) United States
(12) Patent Application Publication
(10) Pub. No.: US 2005/0009367 A1
(43) Pub. Date: Jan. 13, 2005

(54) Novel method to increase fluorine stability to improve gap fill ability and reduce k value of fluorine silicate glass (FSG) film

(75) Inventors: Yi-Lung Cheng, Taipei (TW); Ming-Hwa Yoo, Yung Hu City (TW); Szu-An Wu, Hsin-Chu (TW); Ying-Lang Wang, Lung-Jing (TW); Pei-Fen Chou, Hsin-Chu City (TW)

Correspondence Address: STEPHEN B. ACKERMAN, 28 DAVIS AVENUE, POUGHKEEPSIE, NY, 12603, US

(73) Assignee: Taiwan Semiconductor Manufacturing Co.

(21) Appl. No.: 10/615,744

(22) Filed: Jul. 9, 2003

(51) Int. Cl. H01L 21/76; H01L 21/31; H01L 21/469

(52) U.S. Cl. 438/783; 438/784; 438/788

(57) ABSTRACT

A method of forming an FSG film comprising the following steps. A structure is provided. An FSG film is formed over the structure by an HDP-CVD process under the following conditions: no Argon (Ar)—side sputter; SiF₄ flow: from about 53 to 63 sccm; an N₂ flow: from about 25 to 35 sccm; and an RF power to provide a uniform plasma density.

### FIELD OF THE INVENTION

The present invention relates generally to semiconductor fabrication and more specifically to methods of forming gap-filling films between metal structures.

### BACKGROUND OF THE INVENTION

Fluorine silicate glass (FSG) films still suffer from thermal stability issues. The high density plasma chemical vapor deposition (HDP-CVD) deposition rate of FSG films is about 3200 Å/minute which is lower than a CVD deposition of silicon oxide (SiO₂). The dielectric constant (k) of conventional FSG film is 3.70 and the gap fill for conventional FSG film can only reach 0.21 μm aspect ratio.

U.S. Pat. No. 6,077,764 to Sugiarto et al. describes an FSG deposition process including an N₂ flow during deposition.

U.S. Pat. No. 6,221,793 B1 to Ngo et al. describes an oxide deposition process including an N₂ flow during deposition.

U.S. Pat. No. 5,827,785 to Bhan et al. describes an FSG process that includes an N-containing gas (NF₃).

U.S. Pat. No. 5,429,995 to Nishiyama et al. describes a nitrogen and FSG layer.

U.S. Pat. No. 6,242,338 to Liu et al. describes an N₂ plasma treatment of an FSG layer.

U.S. Pat. No. 6,136,680 to Lai et al. describes various treatments of FSG including a nitrogen-treatment.

U.S. Pat. No. 6,103,601 to Lee et al. describes an FSG process and a post treatment.

### SUMMARY OF THE INVENTION

Accordingly, it is an object of one or more embodiments of the present invention to provide an improved method of forming an FSG film.

Other objects will appear hereinafter.

It has now been discovered that the above and other objects of the present invention may be accomplished in the following manner. Specifically, a structure is provided. An FSG film is formed over the structure by an HDP-CVD process under the following conditions: no Argon (Ar)—side sputter; SiF₄ flow: from about 53 to 63 sccm; an N₂ flow: from about 25 to 35 sccm; and an RF power to provide a uniform plasma density.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1 and 2 schematically illustrate a preferred embodiment of the present invention.

### DETAILED DESCRIPTION OF THE PREFERRED EMBODIMENT

Unless otherwise specified, all structures, layers, steps, methods, etc. may be formed or accomplished by conventional steps or methods known in the prior art.

Problem Known to the Inventors—Not to be Considered Prior Art

When gaps/openings between metal structures/lines are filling with FSG using conventional HDP-CVD deposition recipes, the corners of the metal structures/lines are clipped off due to sputtering conducted at about a 45° angle.

Brief Summary of the HDP-CVD Recipe of the Present Invention

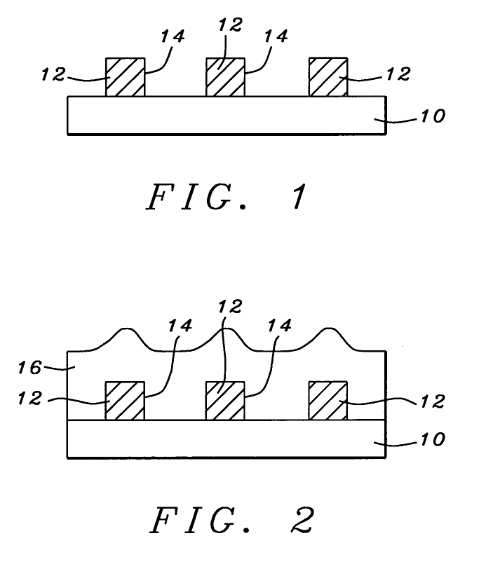

The HDP-CVD recipe of the present invention includes, inter alia:
1) nitrogen (N₂) gas is introduced during the formation of the HDP-CVD FSG to form N-FSG wherein the nitrogen traps free fluorine (F) to prevent the fluorine from diffusing out from the formed N-FSG film;
2) a higher SiF₄ flow rate/low bias RF during the HDP-CVD deposition of the N-FSG is used to improve gap fill ability and to eliminate metal structure/line corner clipping; and
3) the RF power is modified to achieve uniform plasma density to achieve deposition of a uniform N-FSG film.
   Initial Structure—FIG. 1

As shown in FIG. 1, a structure 10 includes at least a pair of adjacent structures 12 formed thereover with respective gaps 14 there between.

Structure 10 is preferably a silicon substrate and is understood to possibly include a semiconductor wafer or substrate, active and passive devices formed within the wafer, conductive layers and dielectric layers (e.g., inter-poly oxide (IPO), intermetal dielectric (IMD), etc.) formed over the wafer surface. The term “semiconductor structure” is meant to include devices formed within a semiconductor wafer and the layers overlying the wafer.

Structures 12 are preferably metal structures or lines and are preferably comprised of copper, aluminum or gold and are more preferably copper or aluminum.

The gaps 14 between a pair of adjacent structures 12 are preferably from about 0.19 to 0.21 μm and may be as narrow as from about 0.17 to 0.21 μm.

Formation of N-FSG Film 16—FIG. 2

As shown in FIG. 2, a nitrogen doped high density plasma chemical vapor deposition (HDP-CVD) fluorine silicate glass (FSG) film 16 (N-FSG) is formed over metal structures/lines 12, filling the respective gaps 14 between adjacent pairs of metal structures/lines 12 in accordance with the recipe of the present invention as describe in detail below.

HDP-CVD Recipe of the Current Invention

Table I below summarizes the more preferable conditions under which the N-FSG film 16 of the present invention is formed and also lists the conditions of the formation of conventional FSG films for comparison.

TABLE I

| | | Present Invention |
|---|---|---|
| Parameter | Conventional | (all more preferably) |
| Argon (Ar) - side | 50 sccm | 0 sccm |
| Ar - top | 5 sccm | about 5 sccm |
| SiH₄ flow - side | 40 sccm | about 53 sccm |
| SiH₄ flow - top | 3.5 sccm | about 3.0 sccm |
| O₂ flow | 102 sccm | about 138 sccm |
| SiF₄ flow | 30 sccm | about 58 sccm |
| N₂ flow | 0 sccm | about 30 sccm |
| RF - top power | 1500 W | about 1500 W |
| RF - side power | 2 W | about 3400 W |
| Bias RF power | 2500 W | 2600 W |

It is noted from Table I that in the present invention compared to the conventional process/recipe: the Ar—side is eliminated to decrease the sputter effect and so prevents corner clipping; a greater quantity of SiH₄—side is employed; a greater flow of O₂ is employed; a greater flow of SiF₄ is employed to increase F etch ability; N₂ is added during the deposition of the N-FSG to trap fluorine to prevent [F] outgassing; and the RF power (RF—top, RF—side and Bias RF) is fine tuned to achieve a uniform plasma density.

The preferably conditions for Table I are:
Ar—side: 0 sccm;
Ar—top: from about 4 to 6 sccm;
SiH₄ flow—side: from about 50 to 56 sccm;
SiH₄ flow—top: from about 2.8 to 3.2 sccm;
O₂ flow: from about 133 to 143 sccm;
SiF₄ flow: from about 53 to 63 sccm;
N₂ flow: from about 25 to 35 sccm;
RF—top: from about 1450 to 1550W;
RF—side: from about 3300 to 3500W; and
bias RF: from about 2575 to 2625 sccm.

Further, the following Table II compares selected characteristics of the convention recipe FSG film to the more preferably characteristics those of the present invention recipe N-FSG film 16:

TABLE II

| | | | THK | WIW | | Dep | | |
|---|---|---|---|---|---|---|---|---|
| | k | Gap fill | U % | Range | D/E | Rate | % F | % F % U |
| FSG | 3.712 | 0.21 μm | 1.88% | 700 Å | 2.55 | 3200 Å/min | 4.35% | 3.53% |
| recipe | | | | | | | | |
| N-FSG | about | about | about | about | about | about | about | about |
| recipe | 3.467 | 0.18 μm | 1.78% | 300 Å | 2.68 | 4600 Å/min | 7.10% | 2.5% |

where:
FSG recipe=convention FSG recipe;
N-FSG recipe=present invention FSG recipe;
THK U%=variation of thickness within a wafer (standard deviation mean)
WIW Range=variation of thickness wafer-to-wafer in a lot
D/E=deposition rate/(etch rate+sputter rate); the index of gap ability
Dep Rate=deposition rate
F%=% atomic concentration
%F%U=variation of F% concentration within a wafer

The preferably characteristics of the N-FSG film 16 for Table II are:
k: from about 3.3 to 3.5;
gap fill: from about 0.17 to 0.19 μm;
THK U%: from about 1.75 to 1.81%;
WIW range: from about 250 to 350 Å;
D/E: from about 2.65 to 2.71;
deposition rate: from about 4400 to 4800 Å;
%F: from about 6.80 to 7.40%; and
%F%U: from about 2.3 to 2.7%.

It is noted from Table II that the N-FSG film 16 of the present invention as compared to the convention FSG film has: a lower dielectric constant (k) which can reduce line to line (L/L) capacitance about 8%; better gap filling ability (an aspect ratio of about 3.5:1); a lower THK U%; a lower range; a higher D/R; a greater deposition rate (by about 40%); a higher percentage of fluorine; and a lower F%U%.

Further, the N-FSG film 16 was found to be more stable than the conventional recipe FSG film as to, inter alia: the F%; lack of F outgassing; lack of formation of Si—OH bonds; thermal stability; and high moisture resistance.

The inventors have determined that no Si—OH peak in a Fourier transform infrared spectrum (FTIR) was detected after one week in the N-FSG film 16 formed in accordance with the present invention. Thus, without the presence of Si—OH bonds formed on the N-FSG film 16, water (H₂O) will not be absorbed by the N-FSG film 16. Also, no bubble after 7 alloys (at about 400° C., N₂, 45 minute furnace for 7 times—worse case for thermal test) was detected on a patterned wafer employing the N-FSG film 16 of the present invention meaning that fluorine within the N-FSG film 16 was stable and did not outgas, attacking metal structures/lines 14.

As way of example, the inventors have determined the following film quality comparison experimental data between a conventional FSG recipe (SID) film and a present invention FSG recipe film (NFSG):

| | SID | NFSG |
|---|---|---|
| Deposition Rate | 3194 | 4348 |
| WIW Range | 756 Å | 312 Å |
| [F] Range | 0.092 | 0.073 |
| Dry Etching Rate | 5099 Å/min | 5795 Å/min |
| Dep/Etch Ratio | 2.42269188 | 2.585142857 |
| Total [F] | 4.491% | 9.943% |
| Total F %/Film F % | 1.080346404 | 1.373722023 |
| Film Stress | −7.55E+08 | −4.61E+08 |

Advantages of the Present Invention

The advantages of one or more embodiments of the present invention include:
1. dielectric constant (k) can be reduced from about 3.4 to 3.5—about an 8% reduction compared to current FSG films;
2. high gap-filling capability, can fill down to 0.17 μm and no need clipping;
3. F in N-FSG recipe keeps the film more stable;
4. higher deposition rate with improved throughput; and
5. the thickness variation for wafer-to-wafer reduced to about 300 Å, improved CMP window.

While particular embodiments of the present invention have been illustrated and described, it is not intended to limit the invention, except as defined by the following claims.

1. A method of forming an FSG film, comprising the steps of:
providing a structure; and
forming an FSG film over the structure by an HDP-CVD process under the following conditions:
a) no Argon (Ar)—side sputter;
b) an SiF₄ flow: from about 53 to 63 sccm;
c) an N₂ flow: from about 25 to 35 sccm; and
d) an RF power to provide a uniform plasma density.

2. The method of claim 1, wherein the structure is comprised of silicon.

3. The method of claim 1, wherein the SiF₄ flow is about 58 sccm and the N₂ flow is about 30 sccm.

4. (canceled)

5. The method of claim 1, wherein the RF power to provide a uniform plasma density includes:
a) an RF top power of about 1500W;
b) an RF side power of about 3400W; and
c) a bias RF power of about 2600 W.

6. The method of claim 1, wherein the FSG film is formed over the structure under the following additional conditions:
a) an Ar top sputter of from about 4 to 6 sccm;
b) an SiH₄ flow—side of from about 50 to 56 sccm;
c) an SiH₄ flow—top of from about 2.8 to 3.2 sccm; and
d) O₂ flow of from about 133 to 143 sccm.

7. The method of claim 1, wherein the FSG film is formed over the structure under the following additional conditions:
a) an Ar top sputter of about 5 sccm;
b) an SiH₄ flow—side of about 53 sccm;
c) an SiH₄ flow—top of about 3.0 sccm; and
d) O₂ flow of about 138 sccm.

8. The method of claim 1, wherein the FSG film includes the following characteristics:
a) a dielectric constant (k) of from about 3.3 to 3.5;
b) a gap filling ability of from about 0.17 to 0.19 μm;
c) a deposition rate of from 4400 to 4800 Å; and
d) a F% of from about 6.80 to 7.40%.

9. The method of claim 1, wherein the formed FSG film includes the following characteristics:
a) a dielectric constant (k) of about 3.4;
b) a gap filling ability of about 0.18 μm;
c) a deposition rate of from 4600 Å; and
d) a F% of from about 7.10%.

10. The method of claim 1, wherein the formed FSG film has a gap filling ability of from about 0.19 to 0.21 μm.

11. The method of claim 1, wherein the formed FSG film has a gap filling ability of from about 0.17 to 0.21 μm.

12. The method of claim 1, wherein the formed FSG film includes the following characteristics:
a) THK U% of from about 1.75 to 1.81%;
b) WIW range of from about 250 to 350 Å;
c) a D/E of from about 2.65 to 2.71; and
d) a %F%U of from about 2.3 to 2.7%.

13. The method of claim 1, wherein the formed FSG film 16 includes the following characteristics:
a) THK U% of from about 1.78%;
b) WIW range of from about 300 Å;
c) a D/E of from about 2.68; and
d) a %F%U of from about 2.5%.

14. The method of claim 1, wherein the formed FSG film does not form appreciable Si—OH bonds within about a week of formation.

15. The method of claim 1, wherein the fluorine within the formed FSG film does not appreciably outgas from the formed FSG film.

16. The method of claim 1, including the step of forming at least two adjacent metal structures upon the structure before the formation of FSG film.

17. The method of claim 1, including the step of forming at least two adjacent metal structures upon the structure and the FSG film is formed over the at least two adjacent metal structures; wherein the at least two adjacent metal structures include corner and wherein the corners of the at least two adjacent metal structures are not clipped by the deposition of the FSG film.

18. The method of claim 1, including the step of forming at least two adjacent metal structures upon the structure and the FSG film is formed over the at least two adjacent metal structures; wherein the at least two adjacent metal structures include corner and wherein the corners of the at least two adjacent metal structures are not clipped by the deposition of the FSG film; the metal structure being comprised of copper, aluminum or gold.

19. The method of claim 1, including the step of forming at least two adjacent metal structures upon the structure and the FSG film is formed over the at least two adjacent metal structures; wherein the at least two adjacent metal structures include corner and wherein the corners of the at least two adjacent metal structures are not clipped by the deposition of the FSG film; the metal structure being comprised of copper or aluminum.

20. A method of forming an FSG film, comprising the steps of:
providing a structure; and
forming an FSG film over the structure by an HDP-CVD process under the following conditions:
a) no Argon (Ar)—side sputter;
b) an SiF₄ flow: from about 53 to 63 sccm;
c) an N₂ flow: from about 25 to 35 sccm; and
d) an RF power to provide a uniform plasma density; wherein the RF power to provide a uniform plasma density includes:
i) an RF top power of from about 1450 to 1550W;
ii) an RF side power of from about 3300 to 3500W; and
iii) a bias RF power of from about 2575 to 2625 W.

21. The method of claim 20, wherein the structure is comprised of silicon.

22. The method of claim 20, wherein the SiF₄ flow is about 58 sccm and the N₂ flow is about 30 sccm.

23. The method of claim 20, wherein the RF power to provide a uniform plasma density includes:
a) an RF top power of about 1500W;
b) an RF side power of about 3400W; and
c) a bias RF power of about 2600 W.

24. The method of claim 20, wherein the FSG film is formed over the structure under the following additional conditions:
a) an Ar top sputter of from about 4 to 6 sccm;
b) an SiH₄ flow—side of from about 50 to 56 sccm;
c) an SiH₄ flow—top of from about 2.8 to 3.2 sccm; and
d) O₂ flow of from about 133 to 143 sccm.

25. The method of claim 20, wherein the FSG film is formed over the structure under the following additional conditions:
a) an Ar top sputter of about 5 sccm;
b) an SiH₄ flow—side of about 53 sccm;
c) an SiH₄ flow—top of about 3.0 sccm; and
d) O₂ flow of about 138 sccm.

26. The method of claim 20, wherein the FSG film includes the following characteristics:
a) a dielectric constant (k) of from about 3.3 to 3.5;
b) a gap filling ability of from about 0.17 to 0.19 μm;
c) a deposition rate of from about 4400 to 4800 Å; and
d) a F% of from about 6.80 to 7.40%.

27. The method of claim 20, wherein the formed FSG film includes the following characteristics:
a) a dielectric constant (k) of about 3.4;
b) a gap filling ability of about 0.18 μm;
c) a deposition rate of about 4600 Å; and
d) a F% of about 7.10%.

28. The method of claim 20, wherein the formed FSG film has a gap filling ability of from about 0.19 to 0.21 μm.

29. The method of claim 20, wherein the formed FSG film has a gap filling ability of from about 0.17 to 0.21 μm.

30. The method of claim 20, wherein the formed FSG film includes the following characteristics:
a) THK U% of from about 1.75 to 1.81%;
b) WIW range of from about 250 to 350 Å;
c) a D/E of from about 2.65 to 2.71; and
d) a %F%U of from about 2.3 to 2.7%.

31. The method of claim 20, wherein the formed FSG film 16 includes the following characteristics:
a) THK U% of from about 1.78%;
b) WIW range of from about 300 Å;
c) a D/E of from about 2.68; and
d) a %F%U of from about 2.5%.

32. The method of claim 20, wherein the formed FSG film does not form appreciable Si—OH bonds within about a week of formation.

33. The method of claim 20, wherein the fluorine within the formed FSG film does not appreciably outgas from the formed FSG film.

34. The method of claim 20, including the step of forming at least two adjacent metal structures upon the structure before the formation of FSG film.

35. The method of claim 20, including the step of forming at least two adjacent metal structures upon the structure and the FSG film is formed over the at least two adjacent metal structures; wherein the at least two adjacent metal structures include corners and wherein the corners of the at least two adjacent metal structures are not clipped by the deposition of the FSG film.

36. The method of claim 20, including the step of forming at least two adjacent metal structures upon the structure and the FSG film is formed over the at least two adjacent metal structures; wherein the at least two adjacent metal structures include corners and wherein the corners of the at least two adjacent metal structures are not clipped by the deposition of the FSG film; the metal structure being comprised of copper, aluminum or gold.

37. The method of claim 20, including the step of forming at least two adjacent metal structures upon the structure and the FSG film is formed over the at least two adjacent metal structures; wherein the at least two adjacent metal structures include corners and wherein the corners of the at least two adjacent metal structures are not clipped by the deposition of the FSG film; the metal structure being comprised of copper or aluminum.

38. A method of forming an FSG film, comprising the steps of:
providing a structure; and
forming an FSG film over the structure by an HDP-CVD process under the following conditions:
a) no Argon (Ar)—side sputter;
b) an SiF₄ flow: about 58 sccm;
c) an N₂ flow: about 30 sccm; and
d) an RF power to provide a uniform plasma density; wherein the RF power to provide a uniform plasma density includes:
i) an RF top power of about 1500W;
ii) an RF side power of about 3400W; and
iii) a bias RF power of about 2600 W.

39. The method of claim 38, wherein the structure is comprised of silicon.

40. The method of claim 38, wherein the FSG film is formed over the structure under the following additional conditions:
a) an Ar top sputter of from about 4 to 6 sccm;
b) an SiH₄ flow—side of from about 50 to 56 sccm;
c) an SiH₄ flow—top of from about 2.8 to 3.2 sccm; and
d) O₂ flow of from about 133 to 143 sccm.

41. The method of claim 38, wherein the FSG mm is formed over the structure under the following additional conditions:
a) an Ar top sputter of about 5 sccm;
b) an SiH₄ flow—side of about 53 sccm;
c) an SiH₄ flow—top of about 3.0 sccm; and
d) O₂ flow of about 138 sccm.

42. The method of claim 38, wherein the FSG film includes the following characteristics:
a) a dielectric constant (k) of from about 3.3 to 3.5;
b) a gap filling ability of from about 0.17 to 0.19 μm;
c) a deposition rate of from about 4400 to 4800 Å; and
d) a F% of from about 6.80 to 7.40%.

43. The method of claim 38, wherein the formed FSG film includes the following characteristics:
a) a dielectric constant (k) of about 3.4;
b) a gap filling ability of about 0.18 μm;
c) a deposition rate of about 4600 Å; and
d) a F% of about 7.10%.

44. The method of claim 38, wherein the formed FSG film has a gap filling ability of from about 0.19 to 0.21 μm.

45. The method of claim 38, wherein the formed FSG film has a gap filling ability of from about 0.17 to 0.21 μm.

46. The method of claim 38, wherein the formed FSG film includes the following characteristics:
a) THK U% of from about 1.75 to 1.81%;
b) WIW range of from about 250 to 350 Å;
c) a D/E of from about 2.65 to 2.71; and
d) a %F%U of from about 2.3 to 2.7%.

47. The method of claim 38, wherein the formed FSG film 16 includes the following characteristics:
a) THK U% of from about 1.78%;
b) WIW range of from about 300 Å;
c) a D/E of from about 2.68; and
d) a %F%U of from about 2.5%.

48. The method of claim 38, wherein the formed FSG film does not form appreciable Si—OH bonds within about a week of formation.

49. The method of claim 38, wherein the fluorine within the formed FSG film does not appreciably outgas from the formed FSG film.

50. The method of claim 38, including the step of forming at least two adjacent metal structures upon the structure before the formation of FSG film.

51. The method of claim 38, including the step of forming at least two adjacent metal structures upon the structure and the FSG film is formed over the at least two adjacent metal structures; wherein the at least two adjacent metal structures include corners and wherein the corners of the at least two adjacent metal structures are not clipped by the deposition of the FSG film.

52. The method of claim 38, including the step of forming at least two adjacent metal structures upon the structure and the FSG film is formed over the at least two adjacent metal structures; wherein the at least two adjacent metal structures include corners and wherein the corners of the at least two adjacent metal structures are not clipped by the deposition of the FSG film; the metal structure being comprised of copper, aluminum or gold.

53. The method of claim 38, including the step of forming at least two adjacent metal structures upon the structure and the FSG film is formed over the at least two adjacent metal structures; wherein the at least two adjacent metal structures include corners and wherein the corners of the at least two adjacent metal structures are not clipped by the deposition of the FSG film; the metal structure being comprised of copper or aluminum.
